(19) United States
(12) Patent Application Publication
(10) Pub. No.: US 2007/0052483 A1
(43) Pub. Date: Mar. 8, 2007

(54) Oscillator

(76) Inventors: Markus Dietl, Muenchen (DE); Gerd Rombach, Freising (DE)

Correspondence Address: TEXAS INSTRUMENTS INCORPORATED, P O BOX 655474, M/S 3999, DALLAS, TX, 75265, US

(21) Appl. No.: 11/366,348

(22) Filed: Mar. 2, 2006

(30) Foreign Application Priority Data
Mar. 9, 2005 (DE) 10 2005 010869.5

(51) Int. Cl. H03L 7/00

(52) U.S. Cl. 331/2

(57) ABSTRACT

An oscillator includes a first oscillator ring with a number of cascaded inverting delay stages and a second oscillator ring with a number of cascaded inverting delay stages. The ring oscillator also includes a number of inverter pairs which each consists of a first inverter and a second inverter, an input of the first inverter being connected with an output of the second inverter and an input of the second inverter being connected with an output of the first inverter. Each inverter pair connects a node of the first oscillator ring with a node of the second oscillator ring. Since phase noise in an oscillator is dominated by the ratio of the power in the edges of the oscillator signal versus the voltage noise that affects the delay of one oscillator stage, essentially all the consumed power is used for the switching process, implementing very steep edges of the oscillator signal.

### CROSS REFERENCE TO RELATED APPLICATIONS

This application claims priority under 35 USC §119 of German Application Serial No. 10 2005 010869.5, filed Mar. 9, 2005.

### FIELD OF THE INVENTION

The present invention relates to an oscillator.

### BACKGROUND OF THE INVENTION

Ring oscillators are widely used in CMOS circuits. A typical ring oscillator is made-up of an odd number of cascaded inverting delay stages connected into a ring. Each stage has an output connected to an input of a following stage, and the connection of an output of a stage with the input of the following stage is called a node. The oscillating frequency of such a ring oscillator is controlled trough the delay caused by each of the stages in the ring. The delay in each stage is due to an inherent capacitance that needs to be charged to a certain voltage level through an associated current source. Accordingly, the delay of each stage in the ring, and thus the oscillation frequency of the ring oscillator, can be controlled by adjusting the current from the current source. A ring oscillator, the oscillation frequency of which is tuned trough a current source, is of a partial-swing type since the voltage drop across the current source detracts from the possible output voltage swing of the delay stages in the ring.

Phase noise performance and a wide frequency pulling range are challenges to ring oscillators for use in advanced communication applications. The present invention provides a ring oscillator that has an improved phase noise performance and a wide pulling range.

### SUMMARY OF THE INVENTION

The ring oscillator according to the present invention comprises a first oscillator ring with a number of cascaded inverting delay stages and a second oscillator ring with a like number of cascaded inverting delay stages. The ring oscillator also includes a like number of inverter pairs which each consists of a first inverter and a second inverter, an input of the first inverter being connected with an output of the second inverter and an input of the second inverter being connected with an output of the first inverter. Each inverter pair connects a node of the first oscillator ring with a node of the second oscillator ring. Due to the presence of the inverter pairs that interconnect corresponding nodes of the two oscillator rings, a 180° phase shift is forced to occur between both rings. More importantly, since inverters in CMOS technology inherently have a full-swing output, the output signal of the ring oscillator is also full-swing, i.e. from rail to rail. Since phase noise in an oscillator is dominated by the ratio of the power in the edges of the oscillator signal versus the voltage noise that affects the delay of one oscillator stage, the invention proposes to use essentially all the consumed power for the switching process, implementing very steep edges of the oscillator signal.

In the preferred embodiment of the invention, the inverting delay stages of the first and second oscillator rings are connected to a single power supply. This leads to a stronger connection of the complementary phases and also determines the power of the switching edges.

Tuning of the oscillator through a wide pulling range is possible with capacitive elements connected to the nodes of the two rings. The nodes of the inverting delay stages are each connected to a capacitive element and the oscillator has an oscillating frequency determined by the capacitance of the capacitive elements. Basically, the invention provides two possible implementations. For a continuous tuning, continuously variable capacitive elements are used. These continuously variable capacitive elements can be achieved in CMOS technology with a MOS transistor the source and drain of which are connected to a node and the gate of which is connected to a control voltage source. The control voltage source supplies a pulsed voltage and the capacitance is controlled by adjusting the duty cycle of the pulsed voltage. In an implementation with digital tuning, each capacitive element is formed by a combination of a plurality of capacitors.

### BRIEF DESCRIPTION OF THE DRAWINGS

Preferred embodiments of the present invention are described hereinafter with reference to the accompanying drawings. In the drawings:

FIG. 1 is a schematic circuit diagram of the inventive oscillator;

FIG. 2 is a circuit diagram of a variable capacitive element; and

FIG. 3 is a schematic circuit diagram of a capacitive element with discrete capacitors.

### DETAILED DESCRIPTION OF THE DRAWINGS

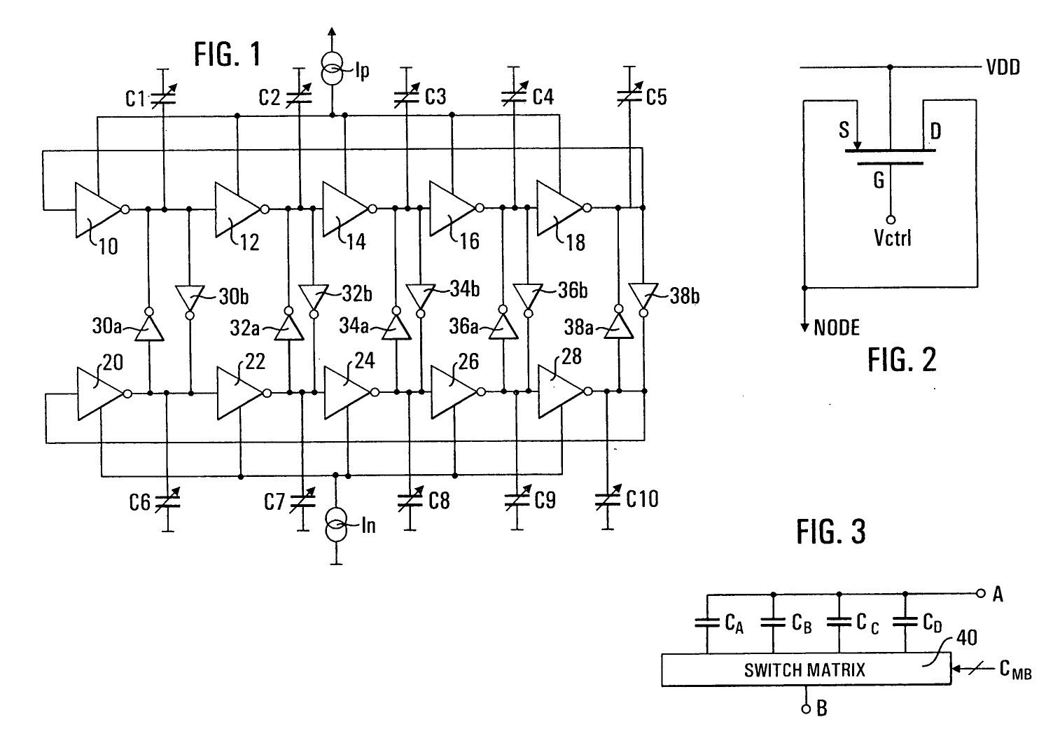

In the CMOS circuit of FIG. 1, a first oscillator ring is made up of five cascaded inverting delay stages 10, 12, 14, 16 and 18. Between successive stages, a node is formed by an output of an upstream stage and an input of a following downstream stage. Stage 18 has an output looped back to the input of stage 10, also forming a node of the oscillator ring. A second oscillator ring is made up of five cascaded inverting delay stages 20, 22, 24, 26 and 28. Again, between successive stages, a node is formed by an output of an upstream stage and an input of a following downstream stage, and stage 28 has an output looped back to the input of stage 20, also forming a node of the oscillator ring.

The nodes between stages 10 and 12, 12 and 14, 14 and 16, 16 and 18 of the first oscillator ring are connected to the nodes between stages 20 and 22, 22 and 24, 24 and 26, 26 and 28 of the second oscillator ring through pairs of inverters 30a and 30b, 32a and 32b, 24a and 34b, 36a and 36b, 38a and 38b, respectively. In each inverter pair, an input of a first inverter is connected with an output of a second inverter. Accordingly, corresponding nodes of the two oscillator rings are coupled by two inverters in opposite directions, thereby the forcing corresponding nodes to be synchronized at exactly 180° of mutual phase shift. As inverters in CMOS technology have a full-swing output (i.e. the output voltage is rail-to-rail), the nodes in both oscillator rings are also full-swing. Also, it should be understood that nearly all the power consumed in the oscillator is consumed in the switching edges.

All stages in both oscillator rings are supplied by just one current source. In FIG., 1, stages 12 to 18 are shown with a supply connection to a positive current supply source Ip, and stages 22 to 28 are shown with a supply connection to a negative current supply source In, it being understood that the stages in both rings all have connections to both of the positive and negative current sources Ip, In.

For tuning the oscillator rings through the desired frequency pulling range, each node of both oscillator rings is connected to an associated variable capacitive element, C1 to C5 in the first ring and C6 to C10 in the second ring. Basically, the capacitive elements can have a continuously variable capacitance or a discontinuously controlled capacitance. FIG. 2 shows an example of a continuously variable capacitance.

A variable capacitive element shown in FIG. 2 is mainly a MOSFET having a source S, a drain D and a gate G, the bulk being connected to a ground potential VDD of the power supply. The source S and drain D of the MOSFET are interconnected and are connected to a node in one of the oscillator rings in FIG. 1. The capacitance of the capacitive element is determined by the level of a control voltage Vctrl applied to the gate G of the MOSFET. If Vₜₕ is the threshold voltage of the MOSFET and the voltage at the corresponding node of the oscillator exceeds the control voltage Vctrl plus the threshold voltage Vₜₕ, then the channel of the MOSFET is open (i.e. conductive), and the inherent capacitance of the MOSFET is effective at the node. Otherwise, the node experiences a much lower capacitance.

In the embodiment of FIG. 3, a variable capacitive element is combined by a selective parallel connection of discrete fixed capacitors C_{A}, C_{B}, C_{C} and C_{D}. In a practical embodiment, many more discrete capacitors could be provided. The capacitors C_{A} to C_{D} all have an electrode connected to a first terminal A and an electrode connected to a switching matrix 40. Switching matrix 40 has an output terminal B and a control input to which a multi-bit digital control signal C_{MB} is applied. An effective capacitance is determined by a selective parallel connection of capacitors CA to CD. The digital control signal C_{MB} determines the switching condition of matrix 40 and thus the effective capacitance across terminals A and B.

1. An oscillator comprising:
a first oscillator ring (14) with a number of cascaded inverting delay stages;
a second oscillator ring (24) with a like number of cascaded inverting delay stages; and
a like number of inverter pairs each consisting of a first inverter and a second inverter, an input of the first inverter being connected with an output of the second inverter and an input of the second inverter being connected with an output of the first inverter,
each inverter pair connecting a node of the first oscillator ring with a node of the second oscillator ring.

2. The oscillator according to claim 1, wherein the inverting delay stages of the first and second oscillator rings are connected to a single power supply.

3. The oscillator according to claim 1, wherein the nodes of the inverting delay stages are each connected to a capacitive element and the oscillator has an oscillating frequency determined by the capacitance of the capacitive elements.

4. The oscillator according to claim 3, wherein the capacitive elements have a variable capacitance.

5. The oscillator according to claim 3, wherein the capacitive elements comprise a plurality of discrete capacitors and the capacitance of a capacitive element is determined by a combination of the discrete capacitors.

6. The oscillator according to claim 3, wherein the capacitive elements are formed by a MOS transistor the source and drain of which are connected to a node and the gate of which is connected to a control voltage source.

7. The oscillator according to claim 6, wherein the capacitance is controlled by adjusting the level of the control voltage.
